(19) United States
(12) Patent Application Publication
(10) Pub. No.: US 2017/0081553 A1
(43) Pub. Date: Mar. 23, 2017

(54) POLISHING COMPOSITION

(71) Applicant: FUJIMI INCORPORATED, Kiyosu-shi, Aichi (JP)

(72) Inventor: Shuichi TAMADA, Kiyosu-shi, Aichi (JP)

(73) Assignee: FUJIMI INCORPORATED, Kiyosu-shi, Aichi (JP)

(21) Appl. No.: 15/126,522

(22) PCT Filed: Feb. 26, 2015
(86) PCT No.: PCT/JP2015/055682

§ 371 Date: Sep. 15, 2016

(30) Foreign Application Priority Data
Mar. 31, 2014 (JP) 2014-071918

(51) Int. Cl. C09G 1/02; H01L 21/02; H01L 21/306; B24B 37/04; C09G 1/04

(52) U.S. Cl. CPC C09G 1/02; B24B 37/044; C09G 1/04; H01L 21/30625; H01L 21/02024

(57) ABSTRACT

The present invention provides a polishing composition suitable for polishing of a polishing object having a layer containing a Group IV material, the polishing composition making it possible to prevent the dissolution of the Group IV material.

The present invention is a polishing composition which contains an oxidizing agent containing a halogen atom and an organic compound containing an amide bond.

### TECHNICAL FIELD

The present invention relates to a polishing composition.

### BACKGROUND ART

In recent years, a new fine processing technology has been developed in accordance with high integration and high performance of LSI. A chemical mechanical polishing (hereinafter, also simply referred to as CMP) method is also one of these technologies, and is often used in an LSI manufacturing process, particularly in flattening an interlayer insulating film in a multilayer wiring forming process, forming a metal plug, and forming embedded wiring (damascene wiring). This technology is disclosed in U.S. Pat. No. 4,944,836, for example. In the damascene wiring technology, it is possible to simplify a wiring process or to improve yield and reliability. Thus, it is believed that application thereof would expand in the future.

In a high-speed logic device, for the damascene wiring, copper is currently mainly used as a wiring metal due to low resistance. Copper is considered to be used also for a memory device represented by a DRAM in the future. In a general method of metal CMP, a polishing pad is attached onto a circular polishing platen, a surface of the polishing pad is impregnated with a polishing agent, a surface of a substrate on which a metal film is formed is pressed against the surface of the polishing pad, and the polishing platen is rotated while a predetermined pressure (hereinafter, also simply referred to as polishing pressure) is applied from the back surface thereof. The metal film of a projecting part is removed by mechanical friction between the polishing agent and the metal film of the projecting part.

On the other hand, on a lower layer of the wiring such as copper or a copper alloy, tantalum, a tantalum alloy, a tantalum compound, or the like is formed as a barrier layer for preventing copper diffusion into an interlayer insulating film. Therefore, in parts other than the wiring part in which copper or a copper alloy is embedded, it is necessary to remove an exposed barrier layer by CMP. However, in general, the barrier layer has a higher hardness than copper or a copper alloy. Therefore, in the case of CMP using a combination of polishing materials for copper or a copper alloy, a sufficient CMP rate is not obtained in many cases.

Meanwhile, tantalum, a tantalum alloy, a tantalum compound, or the like used as a barrier layer is chemically stable, etching thereof is difficult, and mechanical polishing thereof is more difficult than copper or a copper alloy due to a high hardness. Recently, as a material for the barrier layer, a noble metal material such as ruthenium, a ruthenium alloy, or a ruthenium compound has been studied. A noble metal material such as ruthenium, a ruthenium alloy, or a ruthenium compound is excellent in terms of having a lower resistivity than tantalum, a tantalum alloy, or a tantalum compound, being capable of film formation by a chemical vapor deposition method (CVD), and being applicable to narrower width wiring. However, a noble metal material such as ruthenium, a ruthenium alloy, or a ruthenium compound is chemically stable and has a high hardness similar to tantalum, a tantalum alloy, or a tantalum compound. Therefore, polishing thereof is difficult.

A noble metal material is used, for example, as an electrode material in a process for manufacturing a DRAM capacitor structure. Polishing by using a polishing composition is performed for removing a part made of a material containing a noble metal such as a ruthenium simple substance or ruthenium oxide (RuOₓ). However, similar to the above-described noble metal material for a barrier layer, in general, it takes time for removing a material containing a chemically stable noble metal. Therefore, there is a strong need for further improvement of this type of polishing composition in order to enhance throughput.

In general, a polishing agent used for CMP includes an oxidizing agent and abrasive grains. A basic mechanism of CMP by this polishing agent for CMP is considered to be as follows. That is, first, a surface of a metal film is oxidized by an oxidizing agent, and the obtained oxidized layer on the surface of the metal film is scraped off by abrasive grains. An oxidized layer in a recess part of the surface of the metal film does not come into contact with a polishing pad much, and is relatively free from the effect of scrape-off by the abrasive grains. Therefore, the metal film of a projecting part is removed, and a surface of a substrate is flattened in accordance with progress of CMP.

CMP requires a high polishing rate with respect to a wiring metal, stability of the polishing rate, and a low defect density of a polished surface. However, a film containing ruthenium is chemically more stable and has a higher hardness than another damascene wiring metal film such as copper or tungsten. Therefore, it is difficult to polish the film containing ruthenium. As a polishing liquid for such a film containing a noble metal, particularly a film containing ruthenium, for example, in JP 2004-172326 A, a polishing liquid containing polishing abrasive grains, an oxidizing agent, and benzotriazole has been proposed.

As a technology for reducing power consumption of a transistor or improving performance thereof (operating characteristics), a high mobility channel material to increase a mobility of a carrier has been studied. In a channel having these carrier transport characteristics improved, a drain current during ON time is enhanced. Therefore, it is possible to reduce a power supply voltage while a sufficient ON current is obtained. This combination brings about higher performance of MOSFET (metal oxide semiconductor field-effect transistor) at a low power.

As the high mobility channel material, application of a Group III-V compound, a Group IV compound, Ge (germanium), graphene consisting only of C (carbon), or the like is expected. Currently, with regard to forming a Group III-V compound channel, there is a problem that a technology to increase crystallinity of the channel and to control and grow a shape thereof well has not been established. Therefore, a Group IV compound, particularly SiGe, Ge, or the like, which is more easily introduced than the Group III-V compound, has been studied actively.

A channel employing the high mobility material can be formed by polishing a polishing object containing a Group IV compound channel and/or a Ge channel (hereinafter, also referred to as a Ge material part) and a part containing a silicon material (hereinafter, also referred to as a silicon material part). In this case, in addition to polishing the Ge material part at a high polishing rate, it is required not to generate a step which is caused by etching on a surface of the polishing object after the polishing object is polished. For example, JP 2010-130009 A (US 2010/130012 A) and JP 2010-519740 W (US 2011/117740 A) disclose a polishing composition used for polishing a Ge substrate.

### SUMMARY OF INVENTION

However, the polishing compositions described in JP 2010-130009 A (US 2010/130012 A) and JP 2010-519740 W (US 2011/117740 A) have been originally designed for the use of polishing a Ge substrate, and it is difficult to apply them to a polishing object having a layer containing Ge as a material. In particular, dissolution of Ge cannot be prevented, and thus there is a problem that an occurrence of dishing in a Ge material part is difficult to be inhibited.

Accordingly, an object of the present invention is to provide a polishing composition which is useful for polishing a polishing object having a layer containing a Group IV material and for preventing dissolution of a Group IV material.

To solve the problem described above, the inventors of the present invention conducted intensive studies. As a result, it was found that the problem can be solved by using a polishing composition which contains an oxidizing agent containing a halogen atom and an organic compound containing an amide bond. Based on the above finding, the present invention is completed accordingly.

That is, the present invention is a polishing composition which contains an oxidizing agent containing a halogen atom and an organic compound containing an amide bond.

### DESCRIPTION OF EMBODIMENTS

The present invention is a polishing composition which contains an oxidizing agent containing a halogen atom and an organic compound containing an amide bond. By having such a constitution, a polishing composition which is useful for polishing a polishing object having a layer containing a Group IV material and can prevent dissolution of a Group IV material can be provided.

Although the detailed reason for having the aforementioned effect by the polishing composition of the present invention remains unclear, it is believed that the organic compound containing an amide bond plays a role of inhibiting degradation of an oxidizing agent containing a halogen atom and forming a protective film for protecting a layer containing the Group IV material. Meanwhile, the above mechanism is based on a presumption, and the present invention is not at all limited to the above mechanism.

[Polishing Object]

The polishing object according to the present invention is not particularly limited. However, the present invention is preferably used for polishing a polishing object having a layer containing a Group IV material. More specifically, the present invention is used for polishing the polishing object to manufacture a substrate. Examples of the Group IV material include Ge (germanium), SiGe (silicon germanium), and the like.

Next, constitution of the polishing composition of the present invention will be described in detail.

[Oxidizing Agent Containing Halogen Atom]

The oxidizing agent used in the present invention contains a halogen atom. Specific examples of such an oxidizing agent include a halogen acid and a salt thereof; a halous acid or a salt thereof, such as chlorous acid (HClO₂), bromous acid (HBrO₂), iodous acid (HIO₂), sodium chlorite (NaClO₂), potassium chlorite (KClO₂), sodium bromite (NaBrO₂), or potassium bromite (KBrO₂); a halogen acid or a salt thereof, such as sodium chlorate (NaClO₃), potassium chlorate (KClO₃), silver chlorate (AgClO₃), barium chlorate (Ba(ClO₃)₂), sodium bromate (NaBrO₃), potassium bromate (KBrO₃), or sodium iodate (NaIO₃); a perhalogen acid or a salt thereof, such as perchloric acid (HClO₄), perbromic acid (HBrO₄), periodic acid (HIO₄), sodium periodate (NaIO₄), potassium periodate (KIO₄), or tetrabutyl ammonium periodate ((C₄H₉)₄NIO₄); a hypohalous acid such as hypofluorous acid (HFO), hypochlorous acid (HClO), hypobromous acid (HBrO), or hypoiodous acid (HIO); a salt of hypofluorous acid such as lithium hypofluorite (LiFO), sodium hypofluorite (NaFO), potassium hypofluorite (KFO), magnesium hypofluorite (Mg(FO)₂), calcium hypochlorite (Ca(FO)₂), or barium hypofluorite (Ba(FO)₂); a salt of hypochlorous acid such as lithium hypochlorite (LiClO), sodium hypochlorite (NaClO), potassium hypochlorite (KClO), magnesium hypochlorite (Mg(ClO)₂), calcium hypochlorite (Ca(ClO)₂), barium hypochlorite (Ba(ClO)₂), t-butyl hypochlorite (t-BuClO), ammonium hypochlorite (NH₄ClO), or triethanolamine hypochlorite ((CH₂CH₂OH)₃N.ClO); a salt of hypobromous acid such as lithium hypobromite (LiBrO), sodium hypobromite (NaBrO), potassium hypobromite (KBrO), magnesium hypobromite (Mg(BrO)₂), calcium hypobromite (Ca(BrO)₂), barium hypobromite (Ba(BrO)₂), ammonium hypobromite (NH₄BrO), or triethanolamine hypobromite ((CH₂CH₂OH)₃N.BrO); and a salt of hypoiodous acid such as lithium hypoiodite (LiIO), sodium hypoiodite (NaIO), potassium hypoiodite (KIO), magnesium hypoiodite (Mg(IO)₂), calcium hypoiodite (Ca(IO)₂), barium hypoiodite (Ba(IO)₂), ammonium hypoiodite (NH₄IO), or triethanolamine hypoiodite ((CH₂CH₂OH)₃N.IO). These oxidizing agents containing a halogen atom can be used either singly or in mixture of two or more kinds thereof.

Among these oxidizing agents containing a halogen atom, chlorous acid, hypochlorous acid, chloric acid, perchloric acid, and salts thereof are preferable. As the salt, an ammonium salt, a sodium salt, a potassium salt, or the like can be selected.

The lower limit of the concentration of the oxidizing agent in the polishing composition of the present invention is preferably 0.0001% by mass or more, more preferably 0.001% by mass or more, and still more preferably 0.005% by mass or more. Furthermore, the upper limit of the concentration of the oxidizing agent in the polishing composition of the present invention is preferably less than 0.5% by mass, more preferably 0.4% by mass or less, and still more preferably 0.3% by mass or less. Within such a range, a high polishing rate is obtained and processing can be performed efficiently while excessive dissolution of the layer containing a Group IV material is suppressed.

[Organic Compound Containing Amide Bond]

The polishing composition of the present invention contains an organic compound containing an amide bond. The organic compound is a compound which has an amide bond represented by —CO—NR— (CO part has a double bond) in the molecule. By containing this organic compound, it is possible to play a role of inhibiting degradation of an oxidizing agent contained in the polishing composition of the present invention and forming a protective film for protecting the layer containing a Group IV material, and thus the dissolution of the Group IV material can be prevented.

Examples of the organic compound include a compound having a functional group at both ends of the above bond, a compound having a cyclic compound bonded to one end of the above bond, and urea and urea derivatives of which the functional group at both ends is a hydrogen. Specific examples thereof include acetamide, malonamide, succinamide, maleamide, fumaramide,benzamide, naphthoamide, phthalamide, isophthalamide, terephthalamide, nicotinamide, isonicotineamide, formamide, N-methylformamide, propionamide, butylamide, isobutylamide, acrylamide, methacrylamide, palmitamide, stearylamide, oleamide, oxamide, glutaramide, adipamide, cinnamamide, glycolamide, lactoamide, glyceramide, tartaramide, citramide, glyoxylamide, pyruvoamide, acetoacetamide, dimethylacetamide, benzylamide, anthranylamide, ethylene diamine tetraacetamide, diacetamide, triacetamide, dibenzamide, tribenzamide, rhodanine, urea, 1-acetyl-2-thiourea, biuret, butylurea, dibutylurea, 1,3-dimethylurea, 1,3-diethylurea, and a derivative thereof.

In addition, a compound having a structure represented by the following General Formula (1) or General Formula (2) can be mentioned.

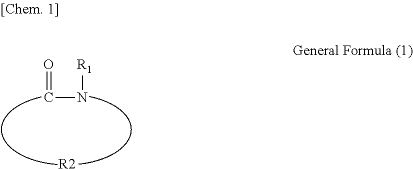

Incidentally, in the above General Formula (1), R₁ represents a hydrogen atom, a hydroxyl group, an aldehyde group, a carbonyl group, a carboxyl group, an amino group, an imino group, an azo group, a nitro group, a nitroso group, a thiol group, a sulfonic acid group, a phosphoric acid group, a halogen group, an alkyl group (a linear, branched or cyclic alkyl group, including a bicycloalkyl group and an active methine group), an aryl group, or an acyl group. These functional groups may have a substituent group or have no substituent group. In General Formula (1), R2 represents a heterocyclic structure having two or more carbon atoms. These functional groups may have a substituent group or have no substituent group.

The substituent group is not particularly limited. However, examples thereof include the followings.

A halogen atom (a fluorine atom, a chlorine atom, a bromine atom, or an iodine atom), an alkyl group (a linear, branched or cyclic alkyl group, including a bicycloalkyl group and an active methine group), an alkenyl group, an alkynyl group, an aryl group, a heterocyclic group (any substitution position), an acyl group, an alkoxycarbonyl group, an aryloxycarbonyl group, a heterocyclic oxycarbonyl group, a carbamoyl group, an N-hydroxy carbamoyl group, an N-acyl carbamoyl group, an N-sulfonyl carbamoyl group, an N-carbamoyl carbamoyl group, a thiocarbamoyl group, an N-sulfamoyl carbamoyl group, a carbazoyl group, a carboxy group or a salt thereof, an oxalyl group, an oxamoyl group, a cyano group, a carbonimidoyl group, a formyl group, a hydroxy group, an alkoxy group (including a group containing repeated units of an ethyleneoxy group or propyleneoxy group), an aryloxy group, a heterocyclic oxy group, an acyloxy group, an (alkoxy or aryloxy) carbonyloxy group, a carbamoyloxy group, a sulfonyloxy group, an amino group, an (alkyl, aryl, or heterocyclic) amino group, an acylamino group, a sulfonamido group, a ureido group, a thioureido group, an N-hydroxy ureido group, an imido group, an (alkoxy or aryloxy) carbonylamino group, a sulfamoylamino group, a semicarbazide group, thiosemicarbazide group, a hydrazino group, an ammonio group, an oxamoylamino group, an N-(alkyl or aryl) sulfonyl ureido group, an N-acylureido group, an N-acyl sulfamoylamino group, a hydroxyamino group, a nitro group, a heterocyclic group containing a quaternary nitrogen atom (for example, a pyridinio group, an imidazolio group, a quinolinio group, or an isoquinolinio group), an isocyano group, an imino group, a mercapto group, an (alkyl, aryl, or heterocyclic) thio group, an (alkyl, aryl, or heterocyclic) dithio group, an (alkyl or aryl) sulfonyl group, an (alkyl or aryl) sulfinyl group, a sulfo group or a salt thereof, a sulfamoyl group, an N-acyl sulfamoyl group, an N-sulfonylsulfamoyl group or a salt thereof, a phosphino group, a phosphinyl group, a phosphinyloxy group, a phosphinylamino group, and a silyl group.

Herein, the active methine group means a methine group substituted with two electron-withdrawing groups. The electron-withdrawing group means an acyl group, an alkoxycarbonyl group, an aryloxycarbonyl group, a carbamoyl group, an alkylsulfonyl group, an arylsulfonyl group, a sulfamoyl group, a trifluoromethyl group, a cyano group, a nitro group, or a carbonimidoyl group. Here, the two electron-withdrawing groups may form a cyclic structure by binding to each other. The salt means a cation such as an alkali metal, an alkaline earth metal, or a heavy metal, or an organic cation such as an ammonium ion or a phosphonium ion.

These substituent groups may be further substituted with a substituent group similar to the above-described substituent group.

Specific examples of the compound represented by the above-described General Formula (1) include 2-pyrrolidone, 1-methyl-2-pyrrolidone, 1-ethyl-2-pyrrolidone, 5-methyl-2-pyrrolidone, 1-(2-hydroxymethyl)-2-pyrrolidone, 1-(2-hydroxyethyl)-2-pyrrolidone, 1-(chloromethyl)-2-pyrrolidone, 1-acetyl-2-pyrrolidone, 5-thioxopyrrolidin-2-one, pyroglutamic acid (D-type, L-type, and DL-type), L-methyl pyroglutamate, ethyl pyroglutamate, succinimide, N-bromosuccinimide, N-chlorosuccinimide, N-iodosuccinimide, N-hydroxysuccinimide, N-methyl succinimide, N-phenyl succinimide, N-methyl-2-phenyl succinimide, 2-ethyl-2-methyl succinimide, hexahydrophthal imide, pyromellitic diimide, hexahydrophthalimide, 2-oxopyrrolidine-1-acetamide, 1-methyl-5-oxo-2-pyrrolidine acetic acid, 2-(2-oxopyrrolidin-1-yl)butanamide, 5-methoxypyrrolidin-2-one, versimide, 4-hydroxy-2-oxo-1-pyrrolidineacetamide, 4-hydroxy-2-pyrrolidone, 1-hydroxy-3-amino-2-pyrrolidone, 1-(2-hydroxyethyl)-2-pyrrolidone, 2-pyrrolidone-5-carboxylic acid,1,2-dihydro-3H-pyrrolizin-3-one, and the like.

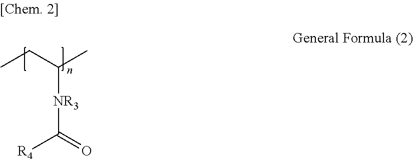

Incidentally, in the above General Formula (2), R₃ and R₄ each independently represents a hydrogen atom, a hydroxyl group, an aldehyde group, a carbonyl group, a carboxyl group, an amino group, an imino group, an azo group, a nitro group, a nitroso group, a thiol group, a sulfonic acid group, a phosphoric acid group, a halogen group, an alkyl group (a linear, branched or cyclic alkyl group, including a bicycloalkyl group and an active methine group), an aryl group, or an acyl group. These functional groups may have a substituent group or have no substituent group. represents the number of a repeat unit.

Specific examples of a compound represented by General Formula (2) include poly-N-vinylacetamide.

These organic compounds containing an amide bond can be used either singly or in mixture of two or more kinds thereof.

The lower limit of the content of the organic compound containing an amide bond in the polishing composition of the present invention is preferably 0.001% by mass or more, more preferably 0.01% by mass or more, and still more preferably 0.1% by mass or more. Furthermore, the upper limit of the content of the organic compound containing an amide bond in the polishing composition of the present invention is preferably 20% by mass or less, more preferably 10% by mass or less, and still more preferably 5 by mass or less. Within such a range, the effect of inhibiting degradation of an oxidizing agent and forming a protective film for protecting a layer containing a Group IV material is further improved.

[Abrasive Grains]

It is preferable that the polishing composition of the present invention further contains abrasive grains. The abrasive grains have an activity of polishing mechanically a polishing object, and thus polishing rate of a polishing object by a polishing composition is improved.

The abrasive grains used for the present invention are not particularly limited. However, specific examples thereof include particles consisting of metal oxide such as silica, alumina, zirconia, or titania. The abrasive grains may be used either singly or in mixture of two or more kinds thereof. Furthermore, a commercially available product or a synthesized product may be used as abrasive grains.

Among those abrasive grains, silica is preferable. Particularly preferred is colloidal silica.

The abrasive grains may be surface-modified. Common colloidal silica has a zeta potential value of nearly zero under acidic conditions, and thus tends to cause agglomeration without electrical repulsion between silica particles under the acidic conditions. In contrast, abrasive grains which have been surface-modified so as to have a relatively large negative zeta potential value even under acidic conditions, are strongly repelled with each other and are well dispersed even under acidic conditions. As a result, the storage stability of the polishing composition is improved. Such surface-modified abrasive grains can be obtained by mixing a metal such as aluminum, titanium, or zirconium, or an oxide thereof with abrasive grains and doping it onto a surface of the abrasive grains.

Among those abrasive grains, an organic acid-immobilized colloidal silica is particularly preferable. An organic acid is immobilized to a surface of colloidal silica contained in the polishing composition, for example, by chemically bonding a functional group of the organic acid to the surface of the colloidal silica. Only by making the colloidal silica and the organic acid coexist, immobilization of the organic acid to the colloidal silica is not achieved. For example, sulfonic acid as an organic acid can be immobilized to colloidal silica by a method described in “Sulfonic acid-functionalized silica through quantitative oxidation of thiol groups”, Chem. Commun. 246-247 (2003). Specifically, colloidal silica of which surface is immobilized with sulfonic acid can be obtained by coupling a silane coupling agent having a thiol group such as 3-mercaptopropyl trimethoxysilane to colloidal silica and then oxidizing the thiol group with hydrogen peroxide. Alternatively, carboxylic acid can be immobilized to colloidal silica by a method described in “Novel Silane Coupling Agents Containing a Photolabile 2-Nitrobenzyl Ester for Introduction of a Carboxy Group on the Surface of Silica Gel”, Chemistry Letters, 3, 228-229 (2000). Specifically, colloidal silica of which surface is immobilized with carboxylic acid can be obtained by coupling a silane coupling agent containing a photoreactive 2-nitrobenzyl ester to colloidal silica and then irradiating the resulting product with light.

The lower limit of an average primary particle diameter of the abrasive grain is preferably 5 nm or more, more preferably 7 nm or more, and still more preferably 10 nm or more. Furthermore, the upper limit of the average primary particle diameter of the abrasive grain is preferably 500 nm or less, more preferably 300 nm or less, and still more preferably 200 nm or less. Within such a range, the polishing rate of the polishing object by the polishing composition is improved, and it is possible to further suppress an occurrence of dishing on the surface of the polishing object after being polished by using the polishing composition. Meanwhile, the average primary particle diameter of the abrasive grain is calculated, for example, based on a specific surface area of the abrasive grain measured by a BET method.

The lower limit of a content (concentration) of the abrasive grains in the polishing composition is preferably 0.0002 g/L or more, more preferably 0.002 g/L or more, and still more preferably 0.02 g/L or more. Furthermore, the upper limit of the content (concentration) of the abrasive grains in the polishing composition is preferably 200 g/L or less, more preferably 100 g/L or less, and still more preferably 50 g/L or less. Within such a range, a high polishing rate is obtained while cost is suppressed, and thus processing can be performed efficiently.

[pH of Polishing Composition]

The pH of the polishing composition of the present invention is preferably 5 or more, and more preferably 7 or more. In addition, the pH of the polishing composition of the present invention is preferably 12 or less, and more preferably 10 or less. Within such a range, polishing can be performed efficiently while excessive dissolution of a polishing object is suppressed.

The pH can be adjusted by adding an appropriate amount of pH adjusting agent. A pH adjusting agent used, if necessary, for adjusting the pH of the polishing composition to a desired value may be either an acid or an alkali, and either an inorganic compound or an organic compound. Specific examples of the acid include an inorganic acid such as sulfuric acid, nitric acid, boric acid, carbonic acid, hypophosphorous acid, phosphorous acid, or phosphoric acid; and an organic acid such as a carboxylic acid including formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, tartaric acid, citric acid, and lactic acid, or an organic sulfuric acid including methanesulfonic acid, ethanesulfonic acid, and isethionic acid. Specific examples of the alkali include a hydroxide of an alkali metal, such as potassium hydroxide; an amine such as ammonia, ethylene diamine, or piperazine; and a quaternary ammonium salt such as tetramethyl ammonium or tetraethyl ammonium. These pH adjusting agents can be used either singly or in mixture of two or more kinds thereof.

[Water]

The polishing composition of the present invention preferably contains water as a dispersion medium or a solvent for dispersing or dissolving each component. Water containing impurities as little as possible is preferable from the viewpoint of suppressing the inhibition of the activity of other components. Specifically, pure water or ultra-pure water obtained by removing foreign matters through a filter after impurity ions are removed using an ion exchange resin, or distilled water is preferable.

[Other Components]

The polishing composition of the present invention may contain, if necessary, other components such as a metal corrosion inhibitor, a preservative, an anti-mold agent, a water soluble polymer, or an organic solvent to dissolve a poorly soluble organic substance. Hereinafter, the metal corrosion inhibitor, the preservative, and the anti-mold agent, which are preferable other components, will be described.

[Metal Corrosion Inhibitor]

By adding a metal corrosion inhibitor to the polishing composition, it is possible to further suppress generation of a recess on a side of the wiring due to polishing using the polishing composition. In addition, it is possible to further suppress an occurrence of dishing on the surface of the polishing object after being polished by using the polishing composition.

The metal corrosion inhibitor which can be used is not particularly limited, but is preferably a heterocyclic compound or a surfactant. The number of members of the heterocyclic ring in the heterocyclic compound is not particularly limited. The heterocyclic compound may be a monocyclic compound or a polycyclic compound having a condensed ring. The metal corrosion inhibitor may be used either singly or in mixture of two or more kinds thereof. As the metal corrosion inhibitor, a commercially available product or a synthetic product may be used.

Specific examples of the heterocyclic compound which can be used as a metal corrosion inhibitor include a nitrogen-containing heterocyclic compound such as a pyrrole compound, a pyrazole compound, an imidazole compound, a triazole compound, a tetrazole compound, a pyridine compound, a pyrazine compound, a pyridazine compound, a pyrindine compound, an indolizine compound, an indole compound, an isoindole compound, an indazole compound, a purine compound, a quinolizine compound, a quinoline compound, an isoquinoline compound, a naphthyridine compound, a phthalazine compound, a quinoxaline compound, a quinazoline compound, a cinnoline compound, a buteridin compound, a thiazole compound, an isothiazole compound, an oxazole compound, an isoxazole compound, and a furazan compound.

More specifically, examples of the pyrazole compound include 1H-pyrazole, 4-nitro-3-pyrazole carboxylic acid, 3,5-pyrazole carboxylic acid, 3-amino-5-phenylpyrazole, 5-amino-3-phenylpyrazole, 3,4,5-bromopyrazole, 3-aminopyrazole, 3,5-dimethylpyrazole, 3,5-dimethyl-1-hydroxymethylpyrazole, 3-methylpyrazole, 1-methylpyrazole, 3-amino-5-methylpyrazole, 4-amino-pyrazolo[3,4-d]pyrimidine, allopurinol, 4-chloro-1H-pyrazolo[3,4-D]pyrimidine, 3,4-dihydroxy-6-methylpyrazolo(3,4-B)-pyridine, 6-methyl-1H-pyrazolo[3,4-b]pyridin-3-amine, and the like.

Examples of the imidazole compound include imidazole, 1-methylimidazole, 2-methylimidazole, 4-methylimidazole, 1,2-dimethylpyrazole, 2-ethyl-4-methylimidazole, 2-isopropylimidazole, benzimidazole, 5,6-dimethylbenzimidazole, 2-aminobenzimidazole, 2-chlorobenzimidazole, 2-methylbenzimidazole, 2-(1-hydroxyethyl)benzimidazole, 2-hydroxybenzimidazole, 2-phenylbenzimidazole, 2,5-dimethylbenzimidazole, 5-methylbenzimidazole, 5-nitrobenzimidazole, 1H-purine, and the like.

Examples of the triazole compound include 1,2,3-triazole, 1,2,4-triazole, 1-methyl-1,2,4-triazole, methyl-1H-1,2,4-triazole-3-carboxylate, 1,2,4-triazole-3-carboxylic acid, 1,2,4-triazole-3-methyl carboxylate, 1H-1,2,4-triazole-3-thiol, 3,5-diamino-1H-1,2,4-triazole, 3-amino-1,2,4-triazole-5-thiol, 3-amino-1H-1,2,4-triazole, 3-amino-5-benzyl-4H-1,2,4-triazole, 3-amino-5-methyl-4H-1,2,4-triazole, 3-nitro-1,2,4-triazole, 3-bromo-5-nitro-1,2,4-triazole, 4-(1,2,4-triazol-1-yl)phenol, 4-amino-1,2,4-triazole, 4-amino-3,5-dipropyl-4H-1,2,4-triazole, 4-amino-3,5-dimethyl-4H-1,2,4-triazole, 4-amino-3,5 dipeptyl-4H-1,2,4-triazole, 5-methyl-1,2,4-triazole-3,4-diamine, 1H-benzotriazole, 1-hydroxybenzotriazole, 1-aminobenzotriazole, 1-carboxybenzotriazole, 5-chloro-1H-benzotriazole, 5-nitro-1H-benzotriazole, 5-carboxy-1H-benzotriazole, 5-methyl-1H-benzotriazole, 5,6-dimethyl-1H-benzotriazole, 1-(1′,2′-di-carboxyethyl)benzotriazole, 1-[N,N-bis(hydroxyethyl)aminomethyl]benzotriazole, 1-[N,N-bis(hydroxyethyl)aminomethyl]-5-methylbenzotriazole, 1-[N,N-bis(hydroxyethyl)aminomethyl]-4-methylbenzotriazole, and the like.

Examples of the tetrazole compound include 1H-tetrazole, 5-methyltetrazole, 5-aminotetrazole, 5-phenyltetrazole, and the like.

Examples of the indazole compound include 1H-indazole, 5-amino-1H-indazole, 5-nitro-1H-indazole, 5-hydroxy-1H-indazole, 6-amino-1H-indazole, 6-nitro-1H-indazole, 6-hydroxy-1H-indazole, 3-carboxy-5-methyl-1H-indazole, and the like.

Examples of the indole compound include 1H-indole, 1-methyl-1H-indole, 2-methyl-1H-indole, 3-methyl-1H-indole, 4-methyl-1H-indole, 5-methyl-1H-indole, 6-methyl-1H-indole, 7-methyl-1H-indole, 4-amino-1H-indole, 5-amino-1H-indole, 6-amino-1H-indole, 7-amino-1H-indole, 4-hydroxy-1H-indole, 5-hydroxy-1H-indole, 6-hydroxy-1H-indole, 7-hydroxy-1H-indole, 4-methoxyl-1H-indole, 5-methoxyl-1H-indole, 6-methoxyl-1H-indole, 7-methoxyl-1H-indole, 4-chloro-1H-indole, 5-chloro-1H-indole, 6-chloro-1H-indole, 7-chloro-1H-indole, 4-carboxy-1H-indole, 5-carboxy-1H-indole, 6-carboxy-1H-indole, 7-carboxy-1H-indole, 4-nitro-1H-indole, 5-nitro-1H-indole, 6-nitro-1H-indole, 7-nitro-1H-indole, 4-nitrile-1H-indole, 5-nitrile-1H-indole, 6-nitrile-1H-indole, 7-nitrile-1H-indole, 2,5-dimethyl-1H-indole, 1,2-dimethyl-1H-indole, 1,3-dimethyl-1H-indole, 2,3-dimethyl-1H-indole, 5-amino-2,3-dimethyl-1H-indole, 7-ethyl-1H-indole, 5-(aminomethyl)indole, 2-methyl-5-amino-1H-indole, 3-hydroxymethyl-1H-indole, 6-isopropyl-1H-indole, 5-chloro-2-methyl-1H-indole, and the like.

Among those heterocyclic compounds, the triazole compound is preferable. Particularly, 1H-benzotriazole, 5-methyl-1H-benzotriazole, 5,6-dimethyl-1H-benzotriazole, 1-[N,N-bis (hydroxyethyl) aminomethyl]-5-methylbenzotriazole, 1-[N,N-bis (hydroxyethyl) aminomethyl]-4-methylbenzotriazole, 1,2,3-triazole, and 1,2,4-triazole are preferable. These heterocyclic compounds have a high chemical or physical adsorption force on the surface of the polishing object, and thus can form a stronger protective film on the surface of the polishing object. This is advantageous in improving the flatness of the surface of the polishing object after being polished by using the polishing composition of the present invention.

The surfactant used as the metal corrosion inhibitor may be any of an anionic surfactant, a cationic surfactant, an amphoteric surfactant, and a nonionic surfactant.

Examples of the anionic surfactant include polyoxyethylene alkyl ether acetate, polyoxyethylene alkyl sulfate ester, alkyl sulfate ester, polyoxyethylene alkyl ether sulfate, alkyl ether sulfate, alkyl benzene sulfonate, alkyl phosphate ester, polyoxyethylene alkyl phosphate ester, polyoxyethylene sulfosuccinate, alkyl sulfosuccinate, alkyl naphthalene sulfonate, alkyl diphenyl ether disulfonic acid, and salts thereof, and the like.

Examples of the cationic surfactant include an alkyl trimethyl ammonium salt, an alkyl dimethyl ammonium salt, an alkyl benzyl dimethyl ammonium salt, and an alkylamine salt, and the like.

Examples of the amphoteric surfactant include alkyl betaine and alkylamine oxide, and the like.

Examples of the nonionic surfactant include polyoxyethylene alkyl ether, polyoxyalkylene alkyl ether, a sorbitan fatty acid ester, a glycerin fatty acid ester, a polyoxyethylene fatty acid ester, polyoxyethylene alkylamine, and alkyl alkanol amide, and the like.

Among these surfactants, polyoxyethylene alkyl ether acetate, polyoxyethylene alkyl ether sulfate, alkyl ether sulfate, alkyl benzene sulfonate, and polyoxyethylene alkyl ether are preferable. These surfactants have a high chemical or physical adsorption force on the surface of the polishing object, and thus can form a stronger protective film on the surface of the polishing object. This is advantageous in improving the flatness of the surface of the polishing object after being polished by using the polishing composition of the present invention.

[Preservative and Anti-Mold Agent]

Examples of the preservative and anti-mold agent that are used in the present invention include an isothiazoline-based preservative such as 2-methyl-4-isothiazolin-3-one or 5-chloro-2-methyl-4-isothiazolin-3-one, paraoxybenzoate ester, and phenoxyethanol, and the like. These preservatives and anti-mold agents maybe used either singly or in mixture of two or more kinds thereof.

[Method for Manufacturing Polishing Composition]

A method for manufacturing the polishing composition of the present invention is not particularly limited. The polishing composition can be obtained by stirring and mixing an oxidizing agent containing a halogen atom, an organic compound containing an amide bond, and if necessary, another component in water.

The temperature at the time of mixing each component is not particularly limited, but it is preferably from 10 to 40° C. The components may be heated in order to increase a dissolution rate. The mixing time is not particularly limited, either.

[Method for Polishing and Method for Manufacturing Substrate]

As described above, the polishing composition of the present invention is particularly suitably used for polishing a polishing object having a layer containing a Group IV material. Therefore, the present invention provides a method for polishing a polishing object having a layer containing a Group IV material by using the polishing composition of the present invention. In addition, the present invention provides a method for manufacturing a substrate including a process of polishing a polishing object having a layer containing a Group IV material by the above-described polishing method.

As a polishing apparatus, it is possible to use a general polishing apparatus to which a holder for holding a substrate or the like having a polishing object and a motor with a changeable rotating speed and the like are attached, having a polishing platen to which a polishing pad (polishing cloth) can be attached.

As the polishing pad, a general nonwoven fabric, polyurethane, a porous fluororesin, or the like can be used without any particular limitation. The polishing pad is preferably grooved such that a polishing liquid can be stored therein.

Polishing conditions are not particularly limited, either. For example, the rotational speed of the polishing platen is preferably from 10 to 500 rpm, and the pressure applied to a substrate having a polishing object (the polishing pressure) is preferably from 0.5 to 10 psi. A method for supplying a polishing composition to a polishing pad is not particularly limited, either. For example, a method in which a polishing composition is supplied continuously by using a pump or the like can be employed. The supply amount is not limited, but a surface of the polishing pad is preferably covered all the time with the polishing composition of the present invention.

After polishing is completed, the substrate is washed with running water, followed by drying the substrate by flicking off water droplets adhered onto the surface of the substrate by using a spin dryer or the like, and as a result, a substrate having a layer containing the Group IV material is obtained.

### EXAMPLES

The present invention will be described in greater detail with the following Examples and Comparative Examples. However, the technical scope of the present invention is not limited to the following Examples.

### Examples 1 to 9, Comparative Examples 1 to 29

The organic compound containing an amide bond shown in Table 1 was added such that it can have the content in the composition which is described in Table 1. Furthermore, an aqueous solution of sodium hypochlorite (concentration: 5.9% by mass) or an aqueous solution of hydrogen peroxide (concentration: 31% by mass) as an oxidizing agent was admixed under stirring in water (mixing temperature: about 25° C., mixing time: about 10 minutes) such that the content in the composition is 0.03% by mass. Accordingly, the polishing composition of Examples 1 to 9 and Comparative Examples 1 to 29 was prepared. The pH of the polishing composition was adjusted by adding potassium hydroxide (KOH), and was confirmed with a pH meter.

As for the remaining ratio of oxidizing agent (oxidizing agent remaining ratio), content of the oxidizing agent was measured for the composition before storage and the composition after storage for 7 days at 25° C. according to the method described in Notification No. 318 by Ministry of Health, Labor, and Welfare (Sep. 29, 2003), and the calculation was made based on the following formula.

Ratio of remaining oxidizing agent (%)=(Amount of oxidizing agent in polishing composition after storage)/(Amount of oxidizing agent in polishing composition before storage)×100

For measuring the etching rate of a Ge substrate, a Ge substrate (3 cm×3 cm) was immersed for 5 minutes at 43° C. at the immersion conditions (while stirrer being rotated at 300 rpm), and dissolved amount was calculated from the weight change after that. By dividing the dissolved amount with immersion time, the etching rate of a Ge substrate was measured.

Composition of the polishing composition of Examples 1 to 9 and Comparative Examples 1 to 29 and the result of measuring the Ge etching rate and remaining ratio of oxidizing agent are described in the following Table 1.

TABLE 1

Organic compound containing amide
group

| | | Addition | | | | Remaining |
|---|---|---|---|---|---|---|
| | | amount | | | Ge etching | ratio of |
| | | (% by | Oxidizing | | rate | oxidizing |
| | Type | mass) | agent | pH | (A/min) | agent (%) |
| Example 1 | 2-Pyrrolidone | 0.17 | NaClO | 8.9 | 37 | 99 |
| Example 2 | 1-Methyl-2-pyrrolidone | 0.20 | NaClO | 8.3 | 48 | 93 |
| Example 3 | 5-Methyl-2-pyrrolidone | 0.20 | NaClO | 9.4 | 44 | 92 |
| Example 4 | 1-Ethyl-2-pyrrolidone | 0.23 | NaClO | 8.2 | 33 | 81 |
| Example 5 | DL-Pyroglutamic acid | 0.26 | NaClO | 9.2 | 48 | 95 |
| Example 6 | Methyl L-Pyroglutamic acid | 0.29 | NaClO | 7.7 | 34 | 98 |
| Example 7 | Poly-N-vinylacetamide | 0.20 | NaClO | 8.2 | 27 | 87 |
| | (average molecular weight: | | | | | |
| | 10000) | | | | | |
| Example 8 | Poly-N-vinylacetamide | 0.20 | NaClO | 8.1 | 33 | 97 |
| | (average molecular weight: | | | | | |
| | 50000) | | | | | |
| Example 9 | Poly-N-vinylacetamide | 0.20 | NaClO | 8.2 | 34 | 92 |
| | (average molecular weight: | | | | | |
| | 100000) | | | | | |

| | Organic compound | | | | | | |
|---|---|---|---|---|---|---|---|
| | | Presence or | Addition | | | | |
| | | absence of amide | amount (% by | Oxidizing | | Ge etching rate | Remaining ratio of |
| | Type | bond | mass) | agent | pH | (A/min) | oxidizing agent (%) |
| Comparative Example 1 | Absence | Absence | — | NaClO | 8.2 | 248 | 100 |
| Comparative Example 2 | Ammonium lauryl sulfate | Absence | 0.20 | NaClO | 8.0 | 93 | 45 |
| Comparative Example 3 | Polydiallyl dimethyl ammonium | Absence | 0.20 | NaClO | 8.1 | 19 | 9 |
| | chloride copolymer | | | | | | |
| Comparative Example 4 | n-Methyl-D-glucamine | Absence | 0.20 | NaClO | 8.2 | 236 | 46 |
| Comparative Example 5 | Benzotriazole | Absence | 0.20 | NaClO | 8.5 | 247 | 75 |
| Comparative Example 6 | Isophthalic acid | Absence | 0.20 | NaClO | 9.2 | 220 | 92 |
| Comparative Example 7 | 2,4-Hexanedione | Absence | 0.20 | NaClO | 8.2 | 188 | 0 |
| Comparative Example 8 | 3-Chloroacetyl acetone | Absence | 0.20 | NaClO | 8.6 | 28 | 0 |
| Comparative Example 9 | Phenol | Absence | 0.20 | NaClO | 8.6 | 26 | 0 |
| Comparative Example 10 | 4-Chlorophenol | Absence | 0.20 | NaClO | 8.3 | 23 | 0 |
| Comparative Example 11 | 4-Hydroxybenzene sulfonic acid | Absence | 0.20 | NaClO | 8.2 | 8 | 0 |
| Comparative Example 12 | 4-Hydroxybenzoic acid | Absence | 0.20 | NaClO | 8.3 | 9 | 0 |
| Comparative Example 13 | Ethylene bisiminobis[(2- | Absence | 0.20 | NaClO | 7.9 | 108 | 0 |
| | hydroxyphenyl)acetic acid] | | | | | | |
| | (EDDHA) | | | | | | |
| Comparative Example 14 | Heptanoic acid salt | Absence | 0.20 | NaClO | 8.2 | 255 | 88 |
| Comparative Example 15 | 2-Pyrrolidone | Presence | 0.20 | H₂O₂ | 8.1 | 726 | 99 |
| Comparative Example 16 | Ammonium lauryl sulfate | Absence | 0.20 | H₂O₂ | 8.0 | 852 | 100 |
| Comparative Example 17 | Polydiallyl dimethyl ammonium | Absence | 0.20 | H₂O₂ | 8.0 | 595 | 105 |
| | chloride copolymer | | | | | | |
| Comparative Example 18 | n-Methyl-D-glucamine | Absence | 0.20 | H₂O₂ | 8.0 | 580 | 100 |
| Comparative Example 19 | Benzotriazole | Absence | 0.20 | H₂O₂ | 8.0 | 928 | 100 |
| Comparative Example 20 | Isophthalic acid | Absence | 0.20 | H₂O₂ | 8.0 | 909 | 100 |
| Comparative Example 21 | 2,4-Hexanedione | Absence | 0.20 | H₂O₂ | 8.0 | 768 | 100 |
| Comparative Example 22 | N,N-Dimethyl acetoacetamide | Presence | 0.20 | H₂O₂ | 8.0 | 753 | 100 |
| Comparative Example 23 | 3-Chloroacetyl acetone | Absence | 0.20 | H₂O₂ | 7.8 | 742 | 100 |
| Comparative Example 24 | Phenol | Absence | 0.20 | H₂O₂ | 8.0 | 807 | 100 |
| Comparative Example 25 | 4-Chlorophenol | Absence | 0.20 | H₂O₂ | 8.0 | 820 | 100 |
| Comparative Example 26 | 4-Hydroxybenzene sulfonic acid | Absence | 0.20 | H₂O₂ | 8.0 | 913 | 100 |
| Comparative Example 27 | 4-Hydroxybenzoic acid | Absence | 0.20 | H₂O₂ | 8.0 | 933 | 100 |
| Comparative Example 28 | Ethylene bisiminobis[(2- | Absence | 0.20 | H₂O₂ | 8.1 | 937 | 100 |
| | hydroxyphenyl)acetic acid] | | | | | | |
| | (EDDHA) | | | | | | |
| Comparative Example 29 | Heptanoic acid salt | Absence | 0.20 | H₂O₂ | 8.0 | 825 | 100 |

As evidenced by the above Table 1, Ge dissolution is inhibited by the polishing composition of Examples 1 to 9. With regard to the polishing composition of Comparative Examples 2 and 3 and Comparative Examples 8 to 13, the Ge etching rate is low, but the remaining ratio of an oxidizing agent is also low, and thus it was found that the oxidizing agent is degraded by the polishing composition.

### Examples 10 to 19, Comparative Examples 30 to 46

Colloidal silica with average primary particle diameter of 30 nm and average secondary particle diameter of 62 nm as abrasive grains, NaClO as an oxidizing agent containing a halogen, and the compound described in the following Table 3 as an organic compound containing an amide group, each in content described in the following Table 3, were stirred and mixed in water (mixing temperature: about 25° C., mixing time: about 10 minutes) to prepare the polishing composition of Examples 10 to 19 and Comparative Examples 30 to 46. The pH of the polishing composition was adjusted by adding nitric acid (HNO₃) or potassium hydroxide (KOH) to have pH 8.5.

[Polishing Rate]

The Ge substrate and TEOS substrate were polished for a pre-determined time at polishing conditions described in the following Table 2 by using the polishing composition of Examples 10 to 19 and Comparative Examples 30 to 46, and the polishing rate was obtained. The Ge substrate [crystal orientation (100)] was used in form of a coupon (3 cm×3 cm). The polishing rate of Ge substrate was determined based on a difference in weight before and after the polishing. Furthermore, the polishing rate of a TEOS substrate was obtained by dividing by polishing time the difference in the thickness of each film before and after the polishing, which was measured by using an optical interference type film thickness measuring device.

TABLE 2
<Polishing conditions>

Polishing apparatus: Table top polishing apparatus Engis
Polishing pad: Foamed polyurethane
Polishing pressure: 1.0 psi (about 6.9 kPa)
Rotational number of polishing platen: 60 rpm
Supply of polishing composition: discarded after single use
Supply amount of slurry: 100 ml/min
Rotational number of carrier: 40 rpm

Furthermore, in the same manner as above, the Ge etching rate and remaining ratio of oxidizing agent were also measured for the polishing composition of Examples 10 to 19 and Comparative Examples 30 to 46. The results of those evaluations are described in the following Table 3.

TABLE 3

| | | | Organic compound containing amide group | | | Remaining | | |
|---|---|---|---|---|---|---|---|---|
| | Content of | Content of | | Content | | ratio | | TEOS |
| | abrasive | oxidizing agent | | (% by | Ge etching | of oxidizing | Ge polishing | polishing rate |
| | grains (g/L) | (% by mass) | Type | mass) | rate (A/min) | agent (%) | rate (A/min) | (A/min) |
| Example 10 | 20.0 | 0.03 | 2-Pyrrolidone | 0.09 | 19 | 93 | 225 | 7 |
| Example 11 | 20.0 | 0.03 | 2-Pyrrolidone | 0.27 | 15 | 94 | 236 | 8 |
| Example 12 | 20.0 | 0.03 | 2-Pyrrolidone | 0.45 | 5 | 97 | 231 | 7 |
| Example 13 | 20.0 | 0.03 | Poly-N-vinylacetamide | 0.10 | 11 | 95 | 245 | 5 |
| | | | (average molecular weight: 50000) | | | | | |
| Example 14 | 20.0 | 0.03 | Poly-N-vinylacetamide | 0.50 | 13 | 93 | 255 | 8 |
| | | | (average molecular weight: 50000) | | | | | |
| Example 15 | 20.0 | 0.03 | Poly-N-vinylacetamide | 1.0 | 5 | 96 | 260 | 7 |
| | | | (average molecular weight: 50000) | | | | | |
| Example 16 | 20.0 | 0.01 | 2-Pyrrolidone | 0.45 | 3 | 86 | 211 | 8 |
| Example 17 | 20.0 | 0.1 | 2-Pyrrolidone | 0.45 | 45 | 98 | 441 | 15 |
| Example 18 | 50.0 | 0.03 | 2-Pyrrolidone | 0.45 | 16 | 63 | 264 | 60 |
| Example 19 | 100.0 | 0.03 | 2-Pyrrolidone | 0.45 | 15 | 58 | 327 | 120 |
| Comparative | 20.0 | — | 2-Pyrrolidone | 0.09 | 6 | — | 30 | 7 |
| Example 30 | | | | | | | | |
| Comparative | 20.0 | — | Poly-N-vinylacetamide | 0.10 | 6 | — | 26 | 7 |
| Example 31 | | | (average molecular weight: 50000) | | | | | |
| Comparative | 20.0 | — | — | — | 5 | — | 25 | 7 |
| Example 32 | | | | | | | | |
| Comparative | — | 0.03 | — | — | 340 | 97 | 39 | 5 |
| Example 33 | | | | | | | | |
| Comparative | 20.0 | 0.01 | — | — | 211 | 35 | 532 | 8 |
| Example 34 | | | | | | | | |
| Comparative | 20.0 | 0.03 | — | — | 335 | 72 | 750 | 9 |
| Example 35 | | | | | | | | |
| Comparative | 20.0 | 0.06 | — | — | 600 | 94 | 2600 | 10 |
| Example 36 | | | | | | | | |
| Comparative | 20.0 | 0.1 | — | — | 900 | 91 | 3529 | 15 |
| Example 37 | | | | | | | | |
| Comparative | 8.9 | 0.03 | — | — | 368 | 84 | 663 | 19 |
| Example 38 | | | | | | | | |
| Comparative | 26.6 | 0.03 | — | — | 355 | 66 | 1030 | 22 |
| Example 39 | | | | | | | | |
| Comparative | 35.5 | 0.03 | — | — | 330 | 45 | 1250 | 40 |
| Example 40 | | | | | | | | |
| Comparative | 50.0 | 0.03 | — | — | 310 | 33 | 1450 | 60 |
| Example 41 | | | | | | | | |
| Comparative | 100.0 | 0.03 | — | — | 295 | 28 | 1800 | 120 |
| Example 42 | | | | | | | | |
| Comparative | 3.5 | 0.06 | — | — | 600 | 92 | 2100 | 15 |
| Example 43 | | | | | | | | |
| Comparative | 3.5 | 0.1 | — | — | 900 | 93 | 2800 | 20 |
| Example 44 | | | | | | | | |
| Comparative | 35.5 | 0.01 | — | — | 211 | 25 | 1000 | 40 |
| Example 45 | | | | | | | | |
| Comparative | 35.5 | 0.1 | — | — | 900 | 91 | 3529 | 40 |
| Example 46 | | | | | | | | |

As shown in the above Table 3, when the polishing composition of Examples 10 to 19 is used, dissolution of Ge is inhibited and also degradation of an oxidizing agent is inhibited, and thus the polishing rate of Ge substrate is improved.

The present application is based on the Japanese patent application No. 2014-71918 filed on Mar. 31, 2014, and a disclosed content thereof is incorporated herein as a whole by reference.

1. A polishing composition which comprises an oxidizing agent comprising a halogen atom and an organic compound comprising an amide bond.

2. The polishing composition according to claim 1, wherein the polishing composition is used for polishing a polishing object having a layer comprising a Group IV material.

3. The polishing composition according to claim 1, further comprising abrasive grains.

4. A method for polishing a polishing object having a layer comprising a Group IV material by using the polishing composition according to claim 1.

5. A method for manufacturing a substrate which comprises a process of polishing a polishing object having a layer comprising a Group IV material by the polishing method according to claim 4.
